(19) United States
(12) Patent Application Publication
(10) Pub. No.: US 2002/0095632 A1
(43) Pub. Date: Jul. 18, 2002

(54) Method and apparatus for creating and testing a channel decoder with built-in self-test

(75) Inventor: Benoit R. Veillette, Shrub Oak, NY (US)

Correspondence Address: Jack E. Haken, c/o U.S. PHILIPS CORPORATION, Intellectual Property Department, 580 White Plains Road, Tarrytown, NY, 10591, US

(73) Assignee: PHILIPS ELECTRONICS NORTH AMERICA CORPORATION.

(21) Appl. No.: 09/730,659

(22) Filed: Dec. 6, 2000

(51) Int. Cl. G01R 31/28; G06F 11/00

(52) U.S. Cl. 714/733; 714/738

(57) ABSTRACT

The invention provides a method and apparatus for creating and testing a channel decoder with built-in self-test. The method and apparatus consist of simulating any specified channel decoder architecture and operation. The simulated channel decoder is then modified for built-in self-test (BIST). A production test signal is created as a product of the modified channel decoder simulation. A channel decoder patterned after the modified channel decoder simulation is manufactured. The manufactured channel decoder is then tested using the production test signal and BIST.

### FIELD OF THE INVENTION

In general, the invention relates to channel decoders. More specifically, the invention relates to the testing of analog and digital portions of a channel decoder and particularly, to the creation of simulated signals used in the testing.

### BACKGROUND OF THE INVENTION

Channel decoders are electronic systems that receive a signal from a channel and extract the information embedded in this signal. The channel may be a propagation medium such as wires, coaxial cables, fiber optic cables, or in the case of radio-frequency (RF) links, waveguides, the atmosphere or empty space. The channel may also be a storage medium such as a magnetic tape or an optical disk. Channel decoders are composed of analog and digital portions. Typically, these two portions are found on two separate integrated circuits (IC). The analog IC converts an RF (radio frequency) signal to an IF (intermediate frequency) or baseband signal, and the digital IC demodulates this signal. An analog-to-digital converter is a necessary component of a channel decoder and is located on either its analog IC or its digital IC. Because of semiconductor manufacturing processes tolerances and defects, ICs are typically tested for quality and accuracy after fabrication.

The typical test procedure as known in the art is to test an analog IC against its functional specifications. The analog IC specifications are derived from the channel decoding system specifications, but the derived specifications are only an approximation of the actual analog IC behavior. The typical digital IC test ignores the IC's functionality and instead verifies its structure with the help of scannable flip-flop chains. Typical digital testing assumes a certain type of circuit fault, which may not model accurately the full range of physical defects.

The main limitation of current test strategies is that the functionality of the system is not guaranteed. These tests may result in under testing, where some defective parts are not identified, or over testing, which is characterized by the rejection of valid parts. Both effects may also occur simultaneously if there is poor correlation between the test signals and the test metrics versus real life conditions. Only by applying actual signals from a channel at the board level, after the two parts composing the system have been assembled, can all defects be uncovered. However, the signal generator, its interface, and the handler make this test quite expensive.

Additionally, the cost of automatic test equipment (ATE) for IC tests is augmenting rapidly because the frequency and the pin count of devices to be tested are always increasing. As a result, while the production costs of an IC are decreasing due to advances in process technologies, the testing costs are on the rise.

Built-in self-test schemes (BIST), known in the art, reduce the testing cost of the digital IC. The testing cost is reduced by eliminating the need for high-end test equipment, or at least reducing the utilization of high-end equipment. A low-cost test platform may be used efficiently. Improved testing performance is possible since BIST is performed using the normal operating frequency (at speed). Additionally, BIST testing can be performed after deployment of the system in the field therefore providing improved troubleshooting and repair capability. However, the signals used with the digital BIST method known in the art are pseudo-random signals, which are very different from signals encountered in normal operations. Furthermore, the pseudo-random signals are applied one at a time. This slows down testing, as scan chains known in the art need to be loaded before each vector and unloaded afterward.

BIST methods for analog circuits are also known in the art. However, their accuracy usually suffers from sensitivity to process variations. They may also have significant overhead and, they typically focus on components instead of systems.

Thus, there is a need for a method and device for applying a BIST method of testing incorporating real modulated signals to an IC using inexpensive test equipment. Ideally, the testers should supply only power and low frequency control signals to the devices under test and collect the test result.

### SUMMARY OF THE INVENTION

The present invention provides a method and apparatus for creating and testing a channel decoder with built-in self-test. The method and apparatus simulate a specified channel decoder architecture and operation. The simulated channel decoder is then modified for built-in self-test (BIST). A production test signal is created as a product of the modified channel decoder simulation. A channel decoder patterned after the modified channel decoder simulation is manufactured. The manufactured channel decoder is then tested using the production test signal and BIST.

One embodiment of the present invention provides a method and apparatus for modifying a channel decoder for built-in self-test. The method and apparatus include identifying memory resources of the channel decoder. Additionally, a digital test signal is created from a provided test message. The channel decoder is modified dependent on the memory resources and the digital test signal.

Another embodiment provides a method and apparatus for producing a production test signal for a built-in self-test channel decoder. A digital test signal is created from a provided test message. The digital test signal is modulated, and a subset of the modulated digital test signal is selected for use in producing a periodic digital test signal. The production test signal is created based on the selected sequence and is encoded on a storage device.

Additionally, an embodiment provides a method and apparatus for testing a built-in self-test channel decoder. In this embodiment the channel decoders internal memory is initialized. A production test signal is downloaded to the internal memory and a periodic test signal is produced as a timed replication of the production test signal. The periodic test signal may then be supplied to a circuit to be tested.

A further embodiment provides a channel decoder modified for BIST that includes a radio frequency circuit, an intermediate frequency circuit, an analog-to-digital converter, and a digital demodulator. The digital demodulator allows for modification of the channel decoders communication standard. A switch connecting the digital demodulator and the analog to digital converter is present as well as a switch connecting the digital demodulator and the intermediate frequency circuit. The channel decoder also uses a signal generation circuit in communication with the digital demodulator.

The foregoing and other features and advantages of the invention will become further apparent from the following detailed description of the presently preferred embodiment, read in conjunction with the accompanying drawings. The detailed description and drawings are merely illustrative of the invention rather than limiting, the scope of the invention being defined by the appended claims and equivalents thereof.

### BRIEF DESCRIPTION OF THE DRAWINGS

FIG. 1 is a block diagram of one embodiment of a channel decoder modified for Built-in Self-test (BIST), in accordance with the invention;

FIG. 2 is a block diagram of one embodiment of a signal generation circuit, in accordance with the invention;

FIG. 3 is a flow diagram of off-line BIST implementation steps to modify a channel decoder and create a periodic test signal; and

FIG. 4 is a flow diagram of BIST application steps for testing.

### DETAILED DESCRIPTION OF THE PRESENTLY PREFERRED EMBODIMENTS

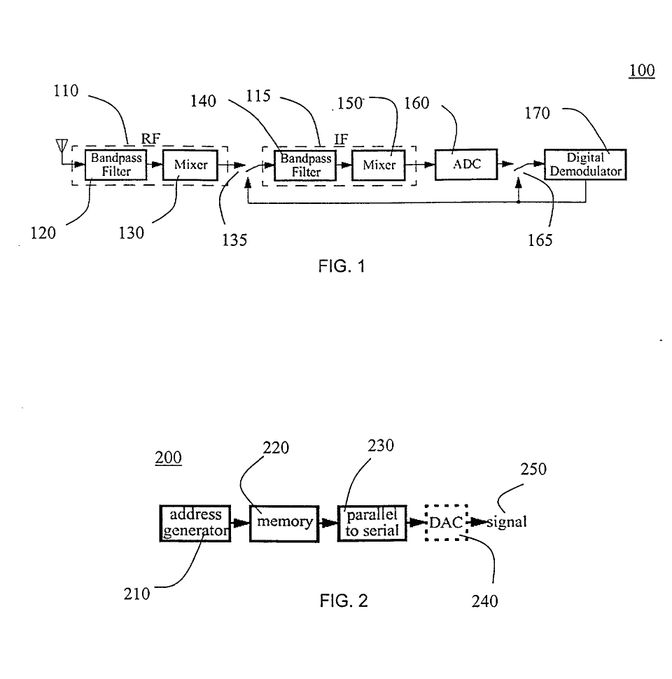

Referring to FIG. 1, one embodiment of a circuit that has been modified for functional built-in self-test (BIST) is generally shown as a channel decoder 100. Radio frequency (RF) circuit 110 can convert an RF signal containing digital data, to an intermediate frequency (IF) signal. The RF circuit can include a bandpass filter 120 and a mixer 130. The IF circuit 115 translates the IF signal to a baseband signal using a bandpass filter 140, and a mixer 150. The baseband signal can be digitized by an analog to digital converter (ADC) 160. In one embodiment, the IF functions are implemented on a single integrated circuit (IC) with the exception of the bandpass filter 140, which is typically realized with a surface acoustic wave (SAW) discrete filter. A digital demodulator 170 demodulates the baseband signal to recover the original digital data. In one embodiment, the ADC 160 can be positioned on the IF circuit 115, but the ADC 160 can also be positioned on the digital demodulator 170. The channel decoder of FIG. 1 can be altered for BIST by adding one of two switches 135,165 to allow the injection of a test signal generated by the digital demodulator 170 at the input of the IF circuit 115, or at the output 165 of the ADC 160, or both.

The signal generation for one embodiment of the BIST scheme requires the periodic playback of an analog (floating point) communication signal encoded on one or more number of bits. To achieve this, first generate off-line a periodic test signal comprised of a long finite-length sequence of samples that embeds a period of a test message. The digital demodulator 170 circuits may require some modifications before the digital demodulator 170 can support this type of signal generation. One embodiment of a signal generation circuit 200 added to a digital demodulator is illustrated in FIG. 2. A periodic test signal 250 can then be generated within the digital demodulator 170.

At test time, the periodic test signal created by the above process with an imbedded test message is downloaded at low speed to a memory bank 220 on the digital demodulator 170. In one embodiment, a RAM memory block that is already present on the digital demodulator 170 is reused as the memory 220, granted the original function of the block containing the memory can be disabled for the duration of the test. Alternatively, a block of RAM can be added to the channel decoder if none can be freed for test use. In another embodiment, ROM can be placed on the integrated chip if the number of tests is small.

An address generator 210 selects a portion of storage or “word” to be read from memory 220 containing the downloaded periodic test signal. Generally, when the memory word size is different from the precision of the signal, and the sample frequency is too large for the memory, a serializer 230 is required. For the testing of the channel decoders digital portion only, the output of the serializer 230 is taken as the periodic test signal 250. For the testing of the combination of the analog and digital portions, a 1-bit DAC 240 is used to generate an analog version of the periodic test signal. The 1-bit DAC elevates the degraded linearity performance associated with a multi-bit DAC as well as reduces the overall cost of the circuit design.

The signal generation circuit 200 repeats the periodic test signal, thus creating a production test signal. Except possibly for the memory block 220, the signal generation circuit 200 requires few additional hardware resources. Most of the computational power is required in the off-line creation 300 of the periodic test signal 250.

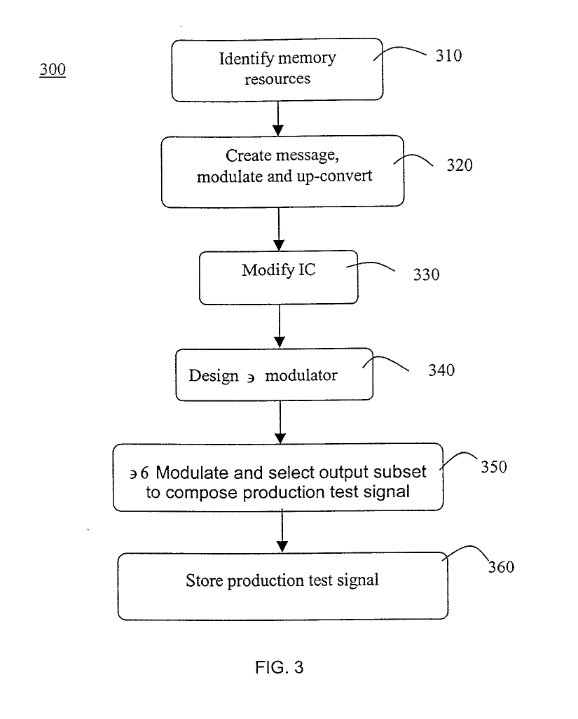

FIG. 3 references the operations that need to be performed before BIST testing can be applied to a channel decoder circuit 100. The following process 300 is performed prior to chip manufacture using computer software known in the art to simulate the required channel decoder operations. First 310 identify the memory resources available in the digital demodulator 170. Ideally, the memory as illustrated for one embodiment as 220, should be from a block that is idle during demodulation. If none is available, a RAM-containing block in the demodulation chain that has simple functionality can be selected. In an alternative embodiment, a RAM module can be added for the express purpose of testing. Additionally, a ROM module could be inserted on the IC if the number and size of test signals is small. Whichever memory block is used, it will have to be tested separately prior to performing BIST on the rest of the circuit.

After identifying memory resources, a test signal with an imbedded test message is created 320. In one embodiment, an imbedded test message is supplied as random symbols created by an external computer. The test message is modulated by the simulation software using algorithms known in the art, producing a continuous time signal that can be sampled. The signal samples form the periodic test signal that can be stored in memory easily. The test message size denoted s in the following equation and expressed in symbols, should be short enough that the number of samples denoted b, will be smaller than the available memory capacity. The relation between the two values is defined by

$$b = s \times \frac{fc}{fs} ,$$

where fc is the sampling (clock) frequency and fs is the symbol frequency. Furthermore, as the test signal will be repeated, it is important that the embedded test message is periodic. The embedding of the test message is governed by a predefined communication standard provided for the specified channel decoder being tested.

In one standard, a frame is the smallest periodic message structure. In that case, the test message must be at least as large as the frame. If the communication standard is very elaborate, it might be necessary to alter some of the parameters of the communication standard for the duration of the BIST operation in order to reduce the test signal size. In another embodiment, the number of segments in a frame is reduced from 313 to 3, shrinking the test message size a hundred fold, also shrinking the test signal. Because the sampling frequency is generally fixed by the system, and both the test message size and the number of samples are integers, the sampling frequency will vary slightly from the standard value. However, this should not be a problem as demodulators are designed to handle such impairment.

The test message can then be modulated according to the preferred communication standard, the first step toward creating the periodic test signal. Typically, modulation is performed in baseband therefore after modulation, the modulated test message is up converted from baseband to the IF frequency to allow for analog testing. At this point additional channel impairments may be added to the up converted, modulated test message. Carrier frequency offset, sampling frequency drift, additive noise, co-channel or adjacent channel interference, impulse noise and static multi-path fading are examples of channel effects that can be modeled. These effects allow for the testing of varying signal conditions. The resulting periodic test signal is utilized next in step 350.

The channel decoder may require slight modifications as previously mentioned, to support BIST 330. In one embodiment the modification is performed by first adding the signal generation circuit 200. One possible way of adding the signal generation circuit 200 is to modify an existing block to have dual functions, however alternative methods may be used. Adding switches where the signal must be injected is also necessary. In one embodiment, the switches are located at the input of the IF circuits 135 and the output of the ADC 165. Finally, the digital demodulator 170 must allow for the altered parameters of the modified communication standard that was defined at the time the message was created 320. The modification to the standard is required to fit the periodic test signal embedding the test message in the available memory 220. In one embodiment, the channel decoder must handle frames with only 3 segments as well as regular frames with 313 segments in order to process the periodic test signal.

The following step 340 is to design a delta-sigma (ΔΣ) modulator. The signal transfer function of the ΔΣ modulator should have unity gain in the signal band. The noise transfer function should be such that the quantization noise in the channel is minimized. The design of ΔΣ modulators is a technique known to those skilled in the art. The up converted modulated test message (periodic test signal) is encoded on a few bits, or on a single bit by the simulation of a ΔΣ modulator performed by the external computer program. Due to the nature of ΔΣ modulation, the output will not be periodic. Taking a subset of the encoded periodic test signal and making it periodic will introduce distortion and increase in-band noise. A search process known in the art is thus necessary to select the sequence from the encoded periodic test signal that minimizes these effects 350. The search results create the production test signal that is then placed 360 on a storage device for utilization by the test procedure 400. The storage device may be of any type known in the art. Any modifications of the channel decoder that were performed during the simulation in the steps described in 330 must be integrated into the actual chip design to utilize this BIST procedure. The channel decoder 100, with any modifications 330, is the resulting product ready for testing.

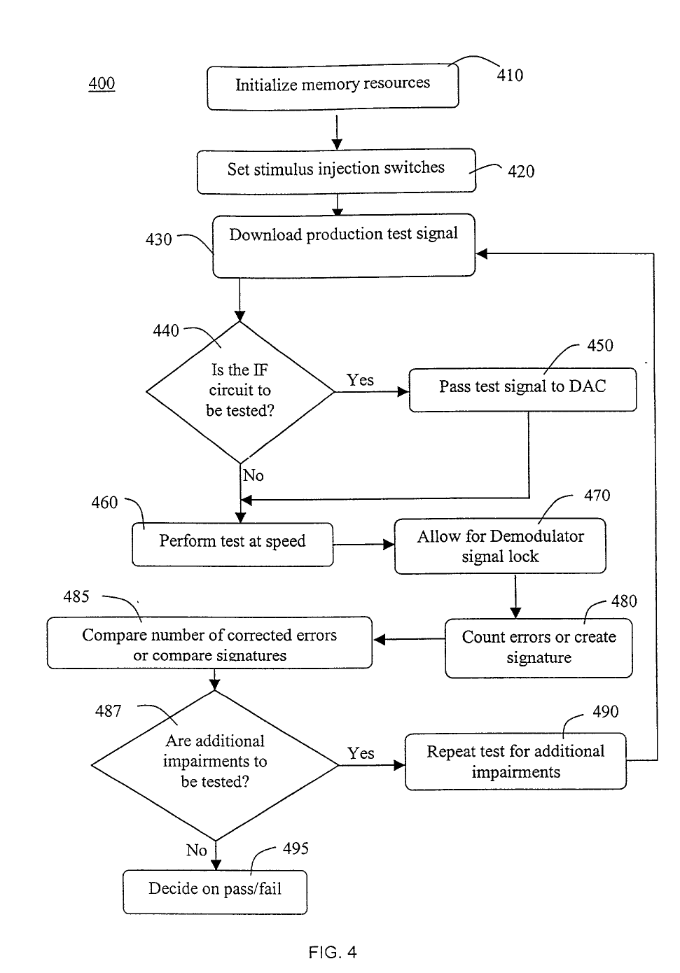

The operations performed by a preferred embodiment of a BIST circuit at test time are summarized in FIG. 4. First, initialize 410 the memory resources 220 previously earmarked for signal generation 310. Any block that contributes memory will have to be by-passed for the duration of the test. In addition, the stimulus injection switches at the input of the IF stage 135 and the input of the digital demodulator 165 are set according to the test selection 420.

The production test signal is then downloaded 430 from the storage device of 360 at low speed to memory 220. To create the periodic test signal, the content of the memory 220 is replicated periodically at high-speed using the circuit of FIG. 1, however alternative embodiments may use alternative circuits. If the input of the IF circuit 115 is selected for test injection 440, then the periodic test signal is passed 450 to a one-bit digital-to-analog converter 240 to create an analog periodic test signal. In one embodiment, a simple first-order RC low pass filter known in the art can be used to reduce the high frequency content of the analog periodic test signal and facilitate its handling by the IF filters Either the digital periodic test signal or the analog periodic test signal can then be applied to the channel decoder under test 460. During BIST operation, a transient time interval where errors are not collected may be necessary for the demodulator 170 to reduce frequency and timing errors and to correct for channel imperfections 470. Afterward, the test results can be obtained. In one embodiment of a channel decoder, the last module in the signal processing chain is an error correction unit. If such a unit is present and has provision for error counting, then it can be used to obtain test results 480. This method is valid for both testing of the digital portion of a channel decoder alone or the combination of the analog portion and the digital portion. In an alternative embodiment, the results of the test of the digital portion may be collected by a multiple-input shift register (MISR). A MISR will create a test signature 480, a technique known in the art. At the end of the test period, this signature is compared with that obtained from a known-good circuit 485. The resulting number of errors or the signature difference are compared with threshold values to check if the channel decoder tested meets the quality requirements 485. The testing process may 487 then be repeated with signals containing impairments such as carrier frequency shift, reduced signal-to-noise ratio, co-channel interference or fading 490. A pass/fail decision is finally made 495. In one embodiment, this decision is governed by the production costs, level of quality required, and specific tests passed or failed however alternative embodiments may contain different pass/fail criteria.

While specific embodiments of the present invention have been shown and described, it will be apparent to those skilled in the art that the disclosed invention may be modified in numerous ways and may assume many embodiments other than those specifically set out and described above. Accordingly, the scope of the invention is indicated in the appended claims, and all changes that come within the meaning and range of equivalents are intended to be embraced therein.

I claim:

1. A method for creating and testing a channel decoder with built-in self-test comprising:
simulating the channel decoder architecture and operation;
modifying the simulated channel decoder for built-in self-test;
creating a production test signal as a product of the modified channel decoder simulation;
manufacturing a channel decoder patterned after the modified channel decoder simulation; and
testing the manufactured channel decoder using the production test signal.

2. The method for claim 1 wherein the production test signal tests a combination of analog and digital circuits of the channel decoder.

3. The method for claim 1 wherein the production test signal tests a digital circuit of the channel decoder.

4. The method for built-in self-test of a channel decoder of claim 1 further comprising collecting a result of the manufactured channel decoder under test using low-end test equipment.

5. The method for claim 4 wherein a transient time interval is performed prior to collecting the result.

6. The method for claim 4 wherein the result is a number of collected errors.

7. The method for claim 4 wherein the result is a signature difference.

8. The method for claim 4 wherein the result is collected by an error correction unit.

9. A method for modifying a channel decoder for built-in self-test comprising:
identifying memory resources of the channel decoder;
creating a periodic test signal from a provided test message; and
modifying the channel decoder dependent on the memory resources and the periodic test signal.

10. The method for modifying a channel decoder of claim 9 further comprising modifying the channel decoders communication standard.

11. The method for modifying a channel decoder of claim 9 wherein the memory resources are located in a digital demodulator.

12. The method for modifying a channel decoder of claim 9 wherein the memory resources are located in a RAM-containing block.

13. The method for modifying a channel decoder of claim 9 wherein the memory resources are located in a RAM module.

14. The method for modifying a channel decoder of claim 9 wherein the memory resources are located in a ROM module.

15. The method for modifying a channel decoder of claim 9 wherein the test message is composed of random symbols.

16. A method for producing a production test signal for a built-in self-test channel decoder comprising:
creating a test message;
modulating the test message;
encoding the modulated test message;
selecting a subset of the encoded, modulated test message;
creating the production test signal based on the selected sequence; and
storing the production test signal on a storage device.

17. The method for producing a production test signal of claim 16 further comprising integrating channel impairments to the modulated digital test signal.

18. The method for producing a production test signal of claim 16 wherein a test message size denoted s and expressed in symbols, is made short enough that a number of samples denoted b, will be smaller than available memory capacity using the relation between the two values
$$b = s \times \frac{fc}{fs} ,$$
where fc is a sampling (clock) frequency and fs is the symbol frequency.

19. The method for producing a production test signal of claim 16 wherein the digital test signal is modulated using a delta-sigma modulator.

20. A method for testing a built-in self-test channel decoder comprising:
initializing internal memory of the channel decoder;
downloading a production test signal to the internal memory;
producing a periodic test signal as a timed replication of the production test signal; and
supplying the periodic test signal to a circuit under test.

21. The method for testing of claim 20 further comprising changing the periodic test signal from digital to analog.

22. The method for testing of claim 20 further comprising integrating signal impairments to the periodic test signal.

23. The method for testing of claim 20 wherein the internal memory is omitted from testing.

24. The method for testing of claim 20 further comprising setting at least one stimulus injection switch to a condition dependent of the channel decoder circuit being tested.

25. The method for testing of claim 20 further comprising reducing a high frequency content of the periodic analog test signal using a first-order RC low pass filter.

26. The method for testing of claim 20 wherein the circuit under test is a combination of analog and digital circuits.

27. The method for testing of claim 20 wherein the circuit under test is digital.

28. A channel decoder made by the process comprising the steps of:
identifying memory resources of the channel decoder;
creating a periodic test signal from a provided test message;
modifying a channel decoder communication standard dependent on the memory resources and the periodic test signal; and
modifying the channel decoder to incorporate the modified communication standard and predefined circuitry.

29. A channel decoder comprising:
a radio frequency circuit;
a intermediate frequency circuit in communication with the radio frequency circuit;
a analog to digital converter in communication with the intermediate frequency circuit;
a digital demodulator in communication with the analog to digital converter wherein the digital demodulator allows for modification of the channel decoders communication standard;
a switch in communication with the digital demodulator and the intermediate frequency circuit; and
a signal generation circuit in communication with the digital demodulator.

30. The channel decoder of claim 29 wherein the switch is in communication with the digital demodulator and the analog to digital converter.

31. The channel decoder of claim 29 wherein the signal generation circuit comprises:
a address generator;
a memory bank in communication with the address generator; and
a serializer in communication with the memory bank.

32. The channel decoder of claim 31 further comprising a digital to analog converter in communication with the serializer.

33. The channel decoder of claim 32 wherein the digital to analog converter is a one bit digital to analog converter.

34. A apparatus for modifying a channel decoder for built-in self-test comprising:
means for identifying memory resources of the channel decoder;
means for creating a periodic test signal from a provided test message; and
means for modifying the channel decoder dependent on the memory resources and the periodic test signal.

35. A apparatus for producing a production test signal for a built-in self-test channel decoder comprising:
means for creating a test message;
means for modulating the test message;
means for encoding the modulated test message;
means for selecting a subset of the encoded, modulated test message;
means for creating the production test signal based on the selected sequence; and
means for storing the production test signal on a storage device.

36. A apparatus for testing a built-in self-test channel decoder comprising:
means for initializing internal memory of the channel decoder;
means for downloading a production test signal to the internal memory;
means for producing a periodic test signal as a timed replication of the production test signal; and
means for supplying the periodic test signal to a circuit under test.

37. A computer readable medium including a computer program for modifying a channel decoder for built-in self-test comprising:
computer readable code for identifying memory resources of the channel decoder;
computer readable code for creating a periodic test signal from a test message; and
computer readable code for modifying the channel decoder dependent on the memory resources and the digital test signal.

38. A computer readable medium including a computer program for producing a production test signal for a built-in self-test channel decoder comprising:
computer readable code for creating a test message;
computer readable code for modulating the test message;
computer readable code for encoding the modulated test message;
computer readable code for selecting a subset of the encoded, modulated test message;
computer readable code for creating the production test signal based on the selected sequence; and
computer readable code for storing the production test signal on a storage device.

39. A computer readable medium including a computer program for testing a built-in self-test channel decoder comprising:
computer readable code for initializing internal memory of the channel decoder;
computer readable code for downloading a production test signal to the internal memory;
computer readable code for producing a periodic test signal as a timed replication of the production test signal; and
computer readable code for supplying the periodic test signal to a circuit under test.
